(19) United States
(12) Patent Application Publication
(10) Pub. No.: US 2018/0306955 A1
(43) Pub. Date: Oct. 25, 2018

(54) OPTICAL PHASE DIFFERENCE COMPONENT, COMPOSITE OPTICAL COMPONENT INCORPORATING OPTICAL PHASE DIFFERENCE COMPONENT, AND METHOD FOR MANUFACTURING OPTICAL PHASE DIFFERENCE COMPONENT

(71) Applicant: JXTG NIPPON OIL & ENERGY CORPORATION, Tokyo (JP)

(72) Inventors: Masanao GOTO, Yokohama-shi (JP); Gorou SUZAKI, Yokohama-shi (JP); Hironao TANAKA, Yamato-shi (JP)

(73) Assignee: JXTG NIPPON OIL & ENERGY CORPORATION, Tokyo (JP)

(21) Appl. No.: 16/020,069

(22) Filed: Jun. 27, 2018

Related U.S. Application Data
(63) Continuation of application No. PCT/JP2017/009116, filed on Mar. 8, 2017.

(30) Foreign Application Priority Data
Mar. 18, 2016 (JP) 2016-054794

(51) Int. Cl. G02B 5/30; C23C 14/06; G03F 7/00; G02B 1/04

(52) U.S. Cl. CPC G02B 5/3083; G02B 1/04; G03F 7/0002; C23C 14/0629

(57) ABSTRACT

An optical phase difference component includes a transparent base with a concave-convex pattern having concave portions and convex portions; a coating layer coating the concave portions and the convex portions of the concave-convex pattern; a gap defined between the convex portions of the concave-convex pattern coated with the coating layer; and a closing layer provided on the concave-convex pattern to connect tops of the convex portions of the concave-convex pattern and to close the gap. A refractive index n₁ of each of the convex portions and a refractive index n₂ of the coating layer at a wavelength of 550 nm satisfy n₂−n₁≤0.8. The optical phase difference component has a phase difference property of reverse dispersion and a wide viewing angle.

### CROSS REFERENCE TO RELATED APPLICATION

This application is a continuation application of International Patent Application No. PCT/JP2017/009116 filed on Mar. 8, 2017 claiming the benefit of priority of Japanese Patent Application No. 2016-054794 filed on Mar. 18, 2016. The contents of International Patent Application No. PCT/JP2017/009116 and Japanese Patent Application No. 2016-054794 are incorporated herein by reference in their entities.

### BACKGROUND

### Field of the Invention

The present invention relates to an optical phase difference component (wave plate or retardation plate), a composite optical component (composite optical member) incorporating the optical phase difference component, and a method for manufacturing the optical phase difference component.

### Description of the Related Art

Optical phase difference plates have so many uses, and are used for various uses such as reflective liquid crystal display devices, semi-transmissive liquid crystal display devices, pickups for optical disks, PS conversion elements, and projectors (projection display devices).

Examples of the optical phase difference plates include those formed by doubly refracting crystal or birefringent crystal that originally exists in the nature, such as calcite, mica, and crystal, those formed by a birefringent polymer, and those formed by artificially providing a periodic structure shorter than a wavelength to be used.

The optical phase difference plate formed by artificially providing the periodic structure is exemplified by an optical phase difference plate provided with a concave-convex structure (concave and convex structure) on a transparent substrate. The concave-convex structure used for the optical phase difference plate has a period (pitch) shorter than a wavelength to be used, and has a pattern such as a stripe pattern as depicted in FIG. 9. Such a concave-convex structure has refractive index anisotropy. When light L enters an optical phase difference plate 400 depicted in FIG. 9 vertically to a substrate 420 of the optical phase difference plate 400, a polarization light component parallel to a periodic direction of the concave-convex structure and a polarization light component vertical to the periodic direction of the concave-convex structure travel in the concave-convex structure at different speeds. This generates a phase difference (retardation) between the two polarization light components. Such a phase difference may be controlled by adjusting, for example, a height (depth) of the concave-convex structure and the difference in refractive indexes between a material of convex portions and a material (air) of gaps between convex portions. The optical phase difference plate to be used in the above-listed devices such as the display devices is required to generate a phase difference of λ/4 or λ/2 (λ represents a wavelength to be used) to a wavelength to be used λ. In order to form the optical phase difference plate that can generate such a sufficient phase difference, there is a need to considerably increase the height (depth) of the concave-convex structure and the difference in refractive indexes between the material of convex portions and the material (air) of gaps between convex portions. As such an optical phase difference plate, Japanese Patent Application Laid-open No. S62-269104 discloses an optical phase difference plate in which a surface (grating 2) of a concave-convex structure is coated with a high refractive index material (dielectric medium 3), as depicted in FIG. 10. Further, Japanese Patent Application Laid-open No. 2004-170623 discloses an optical phase difference plate having a concave-convex structure made from a resin of which refractive index is equal to or more than 1.45.

### SUMMARY

An antireflection film of a display device is required to prevent light reflection in an entire visible region. In order to obtain the antireflection film having such a property, it is ideally desired to use an optical phase difference plate having a property that can generate a phase difference of λ/4 to a wavelength λ in the entire visible region (in the present application, such a phase difference property is referred to as ideal dispersion). An antireflection film using the optical phase difference plate described in Japanese Patent Application Laid-open No. S62-269104, however, can not prevent reflection of all the visible light, causing the film to look colored. In Japanese Patent Application Laid-open No. 2004-170623, a concave-convex structure is made from a resin having a relatively high refractive index by means of imprinting to obtain the optical phase difference plate having a property closer to the ideal dispersion than a phase difference component that is made from a birefringent polymer by means of stretching, namely, to obtain the optical phase difference plate having a property in which a phase difference generated is smaller as a wavelength λ of incident light is shorter (a phase difference generated is larger as the wavelength λ of incident light is longer). In the present application, such a phase difference property is referred to as reverse dispersion or inverse dispersion.

The optical phase difference components described in Japanese Patent Application Laid-open Nos. S62-269104 and 2004-170623, however, have difficulty in generating a desired phase difference for the following reason. When each of the optical phase difference plates is used in a device such as a display device, the optical phase difference plate adheres to another component for use. For example, when the optical phase difference plate is used in an organic EL display device (organic Electro-Luminescence display device or organic light emitting diode display device), a surface of the optical phase difference plate is required to adhere (be joined) to a polarization plate, and the other surface is required to adhere to an organic EL panel (organic Electro-Luminescence panel or organic light emitting diode panel). Adhesive is typically used to cause the optical phase difference plate to adhere to another component. However, as depicted in FIG. 11A, when an optical phase difference plate 400 adheres to another component 320 by use of adhesive, an adhesive 340 enters between convex portions of the concave-convex structure of the optical phase difference plate 400. The refractive index of the adhesive is greater than that of air, and thus the difference in refractive indexes between the material of convex portions and the adhesive entering between convex portions is smaller than the difference in refractive indexes between the material of convex portions and air. Thus, regarding the optical phase difference plate 400 having the adhesive entering between convex portions, the difference in refractive indexes between the material of convex portions and the material of gaps between convex portions is small, which results in small refractive index anisotropy. This makes it impossible for the optical phase difference plate 400 to generate a sufficient phase difference.

Further, the optical phase difference component described in Japanese Patent Application Laid-open No. 2004-170623 looks yellow when seen from an oblique direction, making a viewing angle narrow.

In order that the optical phase difference plate generates a desired phase difference, the concave-convex structure of the optical phase difference plate is required to have both a periodic structure of which period (pitch) is shorter than a wavelength to be used and enough height (depth) of concavities and convexities. Namely, the concave-convex structure is required to have high aspect ratio. When a load is applied on such an optical phase difference plate, however, the concave-convex structure of the optical phase difference plate 400 could be deformed (fall down), making it impossible to generate a desired phase difference, as depicted in FIG. 11B.

An object of the present teaching is to solve the conventional technology problems, to provide an optical phase difference component that has a phase difference property of reverse dispersion, that has a wide viewing angle, and that can generate a desired phase difference even when the component is joined to another component by adhesive or when a load is applied to the component, and to provide a method for manufacturing the optical phase difference component.

According to a first aspect of the present teaching, there is provided an optical phase difference component, including:

a transparent base with a concave-convex pattern having concave portions and convex portions;

a coating layer coating the concave portions and the convex portions of the concave-convex pattern;

a gap defined between the convex portions of the concave-convex pattern coated with the coating layer; and

a closing layer provided on the concave-convex pattern to connect tops of the convex portions of the concave-convex pattern and to close the gap,

wherein a refractive index n₁ of each of the convex portions and a refractive index n₂ of the coating layer at a wavelength of 550 nm satisfy n₂−n₁≤0.8.

According to a second aspect of the present teaching, there is provided a composite optical component, including:

the optical phase difference component as defined in the first aspect; and

a polarization plate adhering to the closing layer or a surface, of the transparent base, opposite to a surface with the concave-convex pattern.

According to a third aspect of the present teaching, there is provided a display device, including:

the composite optical component as defined in the second aspect; and

a display element adhering to the closing layer or a surface, of the transparent base, opposite to a surface with the concave-convex pattern.

According to a fourth aspect of the present teaching, there is provided a method for manufacturing an optical phase difference component, including:

preparing a transparent base with a concave-convex pattern having concave portions and convex portions;

forming a coating layer which coats surfaces of the concave portions and the convex portions of the concave-convex pattern; and

forming a closing layer on the concave-convex pattern to connect adjacent convex portions included in the convex portions coated with the coating layer and to close a gap defined between the adjacent convex portions,

wherein a refractive index n₁ of each of the convex portions and a refractive index n₂ of the coating layer at a wavelength of 550 nm satisfy n₂−n₁≤0.8.

### BRIEF DESCRIPTION OF THE DRAWINGS

FIGS. 1A to 1C each schematically depict an exemplary cross-sectional structure of an optical phase difference component of an embodiment.

FIG. 2A depicts a result acquired by simulating wavelength dependence of a phase difference generated by a concave-convex structure, assuming that a refractive index does not depend on a wavelength but is constant; FIG. 2B conceptually depicts wavelength dependence of a refractive index of a high refractive index material; FIG. 2C conceptually depicts wavelength dependence of a phase difference generated by a conventional optical phase difference component; and FIG. 2D depicts a result acquired by simulating wavelength dependence of a phase difference generated by the optical phase difference component according to the embodiment, assuming that a refractive index of convex portions does not depend on a wavelength but is constant.

FIG. 3 schematically depicts a manufacturing apparatus used for a method for manufacturing the optical phase difference component of the embodiment.

FIG. 4 is a flowchart indicating the method for manufacturing the optical phase difference component of the embodiment.

FIG. 5 is a schematic cross-sectional view of a display device including the optical phase difference component of the embodiment.

FIG. 6 is a graph in which phase differences acquired by simulations in Example 1 and Comparative Example 1 are plotted against wavelengths.

FIG. 7A is a graph in which transmittance of blue light acquired by simulations in Example 1 and Comparative Example 1 is plotted against incident angles; FIG. 7B is a graph in which transmittance of green light acquired by simulations in Example 1 and Comparative Example 1 is plotted against incident angles; and FIG. 7C is a graph in which transmittance of red light acquired by simulations in Example 1 and Comparative Example 1 is plotted against incident angles.

FIG. 8 is a graph in which luminous reflectance acquired by simulations in Example 3 and Comparative Example 3 is plotted against differences in refractive indexes between the high refractive index material and the convex portions.

FIG. 9 schematically depicts an exemplary optical phase difference component of conventional technology.

FIG. 10 is a cross-sectional view of a phase difference component disclosed in Japanese Patent Application Laid-open No. S62-269104.

FIG. 11A is a schematic cross-sectional view of an optical phase difference component of conventional technology, wherein the optical phase difference component adheres to another component with adhesive, and FIG. 11B is a schematic cross-sectional view of the optical phase difference component of the conventional technology, wherein a load is being applied to the optical phase difference component.

### DESCRIPTION OF THE PREFERRED EMBODIMENTS

In the following, embodiments of an optical phase difference component, a method for manufacturing the optical phase difference component, and a composite optical component including the optical phase difference component according to the present teaching will be explained with reference to the drawings.

[Optical Phase Difference Component]

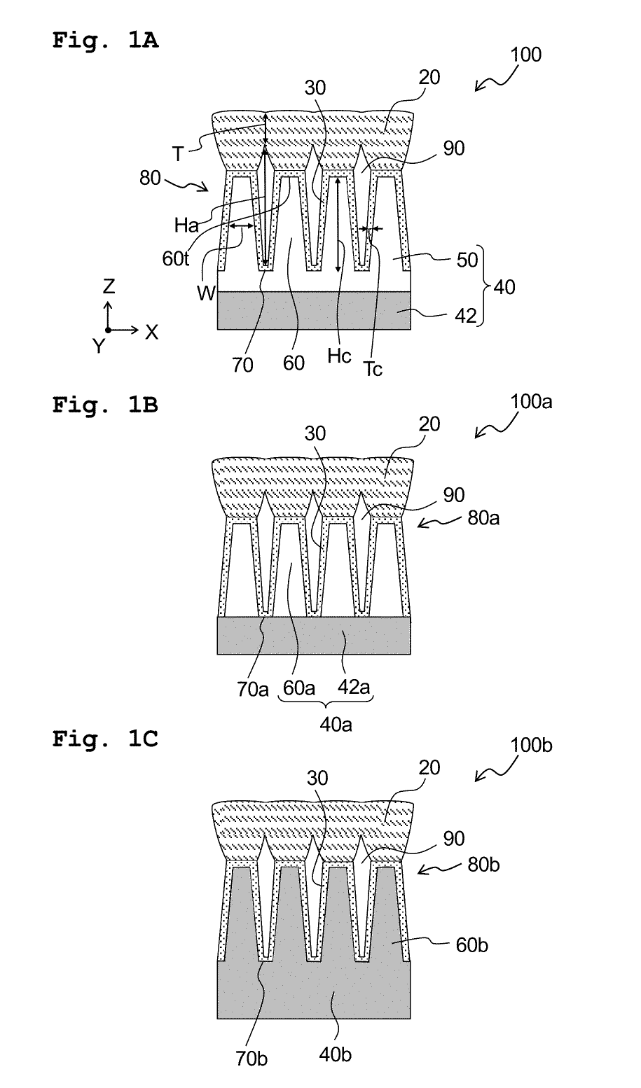

As depicted in FIG. 1A, an optical phase difference component 100 of this embodiment includes a transparent base 40 with a concave-convex pattern 80, a coating layer 30 coating concave portions 70 and convex portions 60 of the concave-convex pattern 80, gaps 90 defined between adjacent convex portions 60 of the concave-convex pattern 80 coated with the coating layer 30, and a closing layer (covering layer or sealing layer) 20 that is disposed on the convex portions 60 and above the gaps 90 (on the concave-convex pattern 80) to connect tops of adjacent convex portions 60. The gaps 90 are surrounded and closed by the closing layer 20 and the concave-convex pattern 80 coated with the coating layer 30.

<Transparent Base>

In the optical phase difference component 100 of this embodiment depicted in FIG. 1A, the transparent base 40 is formed by a plate-shaped substrate or base material 42 and a concave-convex structure layer 50 formed on the substrate 42.

The substrate 42 is not particularly limited, and publicly known substrates transmitting visible light may be used as the substrate 42 as appropriate. As the substrate 42, it is possible to use, for example, light transmissive substrates described in WO2016/056277, including substrates made from transparent inorganic materials such as glass; and substrates made from resins. The substrate 42 desirably has a front phase difference as small as possible. When the optical phase difference component 100 is used for an antireflection film of an organic EL display device, the substrate 42 may be a flexible substrate, for example, a substrate made from a resin. It is allowable to perform a surface treatment for the substrate 42 or to provide an easy-adhesion layer on the substrate 42 so as to improve an adhesion property of the substrate 42 and/or it is allowable to provide a smoothing layer to cover any protrusion on a surface of the substrate 42. The thickness of the substrate 42 may be in a range of 1 μm to 20 mm.

The concave-convex structure layer 50 includes the convex portions 60 and the concave portions 70, whereby a surface of the concave-convex structure layer 50 defines the concave-convex pattern 80. The concave-convex structure layer 50 is made from a material having a refractive index n₁ in which the difference with a refractive index n₂ of the coating layer 30 at a wavelength of 550 nm is equal to or less than 0.8. Namely, n₂−n₁≤0.8 is satisfied at a wavelength of 550 nm. The optical phase difference component 100 that includes the concave-convex structure layer 50 having the refractive index n₁ has a phase difference property of reverse dispersion and a wide viewing angle, as described below. The concave-convex structure layer 50 may be made from a material having a refractive index of equal to or more than 1.6. As materials configuring the concave-convex structure layer 50, it is allowable to use inorganic materials exemplified, for example, by silicon (Si)-based materials such as silica, SiN, and SiON; titanium (Ti)-based materials such as TiO₂; materials based on indium-tin oxide (ITO); and ZnO, ZnS, ZrO₂, Al₂O₃, BaTiO₃, Cu₂O, MgS, AgBr, CuBr, BaO, Nb₂O₅, and SrTiO₂. The above-listed inorganic materials may be materials (sol-gel materials, namely, materials obtained by curing a precursor solution described below) formed by a sol-gel method or the like. In addition to the above inorganic materials, it is possible to use thermoplastic resins; ultraviolet curable resins; resin materials obtained by blending more than two kinds of the above materials; a composite material of the resin material(s) and/or the inorganic material(s); and a material obtained by allowing the above material(s) to contain an ultraviolet absorbent material, those of which are described in WO2016/056277. The above resin materials may include a fluorene skeleton or a norbornene skeleton to improve the refractive index. In order to obtain a hard coating property and the like and/or improve the refractive index, the resin materials and/or the inorganic materials may include publicly known fine particles and/or filler formed from ZrO₂, Nb₂O₅, TiO₂, and the like.

Each convex portion 60 of the concave-convex structure layer 50 extends in a Y direction (a direction perpendicular to the paper surface in the drawing sheet) in FIG. 1A. The convex portions 60 are arranged at pitches shorter than a design wavelength (a wavelength of light for which a phase difference is generated by using the optical phase difference component 100). The cross-section of each convex portion 60 in a ZX plane orthogonal to the extending direction of each convex portion 60 may have a substantially trapezoidal shape. In the present application, the phrase “substantially trapezoidal shape” means a substantially rectangular shape having opposite sides substantially parallel to the surface of the substrate 42, wherein one (base line) of the opposite sides closer to the surface of the substrate 42 is longer than the other (upper line), and angles formed by the base line and two oblique sides are acute angles. Each side of the substantially rectangular shape may be curved. Namely, each convex portion 60 is only required to have a width (a length in a direction orthogonal to the extending direction of the convex portion 60, that is, a length in an X direction in FIG. 1A) that is smaller toward an upper side (in a direction away from the surface of the substrate 42) from the surface of the substrate 42. The top of each convex portion 60 may be rounded. The length of the upper line of each convex portion 60 may be zero. Namely, in the present application, the phrase “substantially trapezoidal shape” is a concept including a substantially triangular shape. When the cross-section of the convex portion 60 has a substantially triangular shape having an upper line length of zero, the height of the convex portion 60 that is required to generate a desired phase difference is lower than a case in which the upper line length exceeds zero. This results in an advantage of making it easy to form the concave-convex pattern. The upper line length of the cross-section of the convex portion 60 may exceed zero. The convex portion having the cross-section of a substantially trapezoidal shape, in which the upper line is greater than zero, has the following advantages over the convex portion having the cross-section of a substantially triangular shape. The advantages include: making it easy to form a mold that is used to form convex portions by an imprinting method; improving a mechanical strength such as a resistance of the convex portion to surface pressing; and shortening deposition time required to form the closing layer 20 which is described below. The cross-sectional shape of the convex portion 60 is not limited to the substantially trapezoidal shape, and may be various shapes such as a rectangular shape and a multangular shape. As described later, in order to form the closing layer 20 easily, a top 60t of the convex portion 60 may be flat, that is, it may have a planar shape parallel to the surface of the substrate 42. The concave portions 70, which are defined by the convex portions 60, extend in the Y direction (the direction perpendicular to the paper surface in the drawing sheet) along the convex portions 60.

Each of the convex portions 60 preferably has a height Hc in a range of 100 to 2000 nm (the height of concavities and convexities is preferably in a range of 100 to 2000 nm). If the height Hc of the convex portion 60 is less than 100 nm, it is difficult to generate a desired phase difference when visible light enters the optical phase difference component 100. If the height Hc of the convex portion 60 exceeds 2000 nm, the aspect ratio of the convex portion 60 (ratio between height and width of the convex portion) is high, thus making it difficult to form the concave-convex pattern. Each of the convex portions 60 may have a width W in a range of 10 to 500 nm. If the width W of the convex portion 60 is less than 10 nm, the aspect ratio of the convex portion 60 (ratio between height and width of the convex portion) is high, thus making it difficult to form the concave-convex pattern. If the width W of the convex portion 60 exceeds 500 nm, coloring of transmitted light occurs, which makes it difficult for the optical phase difference component 100 to have sufficient colorless and transparent properties. Further, the width W of the convex portion 60 exceeding 500 nm makes it difficult for the optical phase difference component 100 to generate a desired phase difference. Furthermore, the width W of the convex portion 60 exceeding 500 nm leads to large intervals between upper parts of adjacent convex portions 60, which makes it difficult to form the closing layer 20 with high strength. Here, the width W of the convex portion 60 means an average value of widths of the convex portions 60 at positions in a Z direction (positions in a height direction). The concave-convex pitch of the concave-convex pattern 80 may be in a range of 100 to 1000 nm. If the pitch is less than 100 nm, it is difficult to generate a desired phase difference when visible light enters the optical phase difference component 100. If the pitch exceeds 1000 nm, it is difficult for the optical phase difference component 100 to have sufficient colorless and transparent properties. Further, the pitch exceeding 1000 nm leads to large intervals between upper parts of adjacent convex portions 60, which makes it difficult to form the closing layer 20 with high strength.

<Coating Layer>

The coating layer 30 coats the transparent base 40 along the concave-convex pattern 80. Namely, the coating layer 30 coats surfaces of the convex portions 60 and the concave portions 70 of the concave-convex pattern 80. The thickness of the coating layer 30 is determined so that the closing layer 20 covering the convex portions 60 and the gaps 90 which are described below can be formed. In that case, the coating layer 30 has a thickness which allows the coating layer 30 is formed between the gap 90 and the convex portion 60 adjacent to the gap 90. If the coating layer 30 is too thick to form the gaps 90 between the coating layer 30 and the closing layer 20, it is impossible to utilize the difference in refractive indexes between the coating layer 30 and air and the like existing in the gaps 90, thus making it difficult for the optical phase difference component 100 to obtain a desired phase difference. The thickness Tc of the coating layer 30 may be equal to or more than 10 nm. In the present application, the phrase “the thickness Tc of the coating layer 30” means a thickness of the coating layer 30 that is formed on a side surface of each convex portion 60 at a position having a height of Hc/2 from the bottom of the convex portion 60, Hc being the height of the convex portion 60.

The coating layer 30 may be made from a material having the refractive index n₂ that is higher than the refractive index n₁ of the material forming the concave-convex structure layer 50. Especially, the coating layer 30 may be made from a material having the refractive index n₂ of 1.8 to 2.6. Coating the convex portions 60 with the coating layer 30 of which refractive index is equal to or more than 1.8 increases a phase difference generated by the periodical arrangement of the convex portions 60 and the gaps 90. With this, it is possible to reduce the height of the convex portions 60, that is, it is possible to reduce the aspect ratio of the convex portions 60, which makes it easy to form the concave-convex pattern 80. A substance of which refractive index exceeds 2.6 is difficult to obtain, or has difficulty in forming a film at temperatures not causing deformation of the substrate 42. Examples of materials forming the coating layer 30 include metals such as Ti, In, Zr, Ta, Nb, and Zn, and inorganic materials such as oxide, nitride, sulfide, oxynitride, and halide of the above metals. The coating layer 30 may be a component containing the above materials.

<Gaps>

The gaps 90 are defined between adjacent convex portions 60. The gaps 90 are surrounded and closed by the coating layer 30 and the closing layer 20. The gaps 90 may be filled with air, an inert gas such as N₂, Ar, and He, other low refractive index mediums, or the like. The gaps 90 may be filled with no medium, namely, the gaps 90 may be a vacuum. Each of the gaps 90 preferably has a height Ha equal to or higher than the height Hc of the convex portions 60. The optical phase difference component 100 generates a phase difference in light transmitted therethrough by the periodical arrangement of the gaps 90 and the coating layer 30. When the height Ha of the gaps 90 is lower than the height Hc of the convex portions 60, the height of the periodic arrangement structure of the gaps 90 and the coating layer 30 is low. This reduces the phase difference generated by the optical phase difference component 100.

<Closing Layer>

The closing layer 20 is formed on the convex portions 60 and above the gaps 90 to cover the convex portions 60 and the gaps 90. The closing layer 20, together with the coating layer 30, surrounds and closes (seals) the gaps 90. In that configuration, when the optical phase difference component 100 of this embodiment is joined to another component by adhesive so as to incorporate the optical phase difference component 100 in a device, the adhesive does not enter the gaps 90 between adjacent convex portions 60. This prevents the phase difference generated by the optical phase difference component 100 from decreasing which would be otherwise caused by the entering of adhesive in the gaps between adjacent convex portions. Thus, even when the optical phase difference component 100 of this embodiment is used in a state of being joined to another component, the optical phase difference component 100 can generate a desired phase difference.

When a load is applied from above the optical phase difference component 100 (from a closing layer 20 side), each convex portion 60 is supported by adjacent convex portions 60 via the closing layer 20. Connecting the convex portions 60 via the closing layer 20 disperses the applied force, reducing the load applied to each convex portion 60. Thus, even when a load is applied to the optical phase difference component 100 of this embodiment, the convex portions 60 of the concave-convex pattern 80 are not likely to be deformed. This prevents a situation in which the optical phase difference component 100 can not generate a desired phase difference due to the load application thereon.

The closing layer 20 may be made from the same material as the coating layer 30. When the material of the closing layer 20 is different from that of the coating layer 30, a layer made from the material forming the closing layer 20 is formed on the coating layer 30, which is formed on the side surface of each convex portion 60. This could reduce the phase difference generated by the periodic arrangement of the gaps 90 and the convex portions 60 and/or make control of the phase difference difficult. The closing layer 20 may have a light transmission property. For example, the closing layer 20 may have transmittance of equal to or more than 90% at a wavelength of 550 nm. The closing layer 20 may have a thickness T in a range of 10 to 1000 nm. In this context, the thickness T of the closing layer 20 means a distance from an upper end of each gap 90 to a surface of the closing layer 20 (see FIG. 1A). When another component is joined to the closing layer 20 side of the optical phase difference component 100, another component is joined to the closing layer 20 via adhesive. Namely, the closing layer 20 is different from the adhesive used for joining the optical phase difference component 100 and another component.

The optical phase difference component 100 of this embodiment has a phase difference property of reverse dispersion, as indicated in Examples described below, by causing the refractive index n₁ of the material forming the concave-convex structure layer 50 and the refractive index n₂ of the material forming the covering layer 30 to satisfy n₂−n₁≤0.8 at a wavelength of 550 nm. The reason thereof is considered by inventors of the present application, as follows.

The optical phase difference component typically has a structure in which materials having mutually different refractive indexes are alternately arranged in one direction. When light (transmitted light) enters the optical phase difference component from a direction substantially parallel to the interface between the materials having mutually different refractive indexes, the phase difference can be generated in the transmitted light (structural birefringence). A conventional optical phase difference component as depicted in FIG. 10 has an interface between a coating layer having a high refractive index and air existing between adjacent convex portions and an interface between the coating layer and each convex portion, as interfaces that are substantially parallel to a travelling direction of transmitted light. Those interfaces generate the phase difference in the transmitted light. Namely, the phase difference properties of the optical phase difference component depicted in FIG. 10 are generally produced by combining the phase difference property obtained from the interface between air and the coating layer with the phase difference property obtained from the interface between the coating layer and each convex portion.

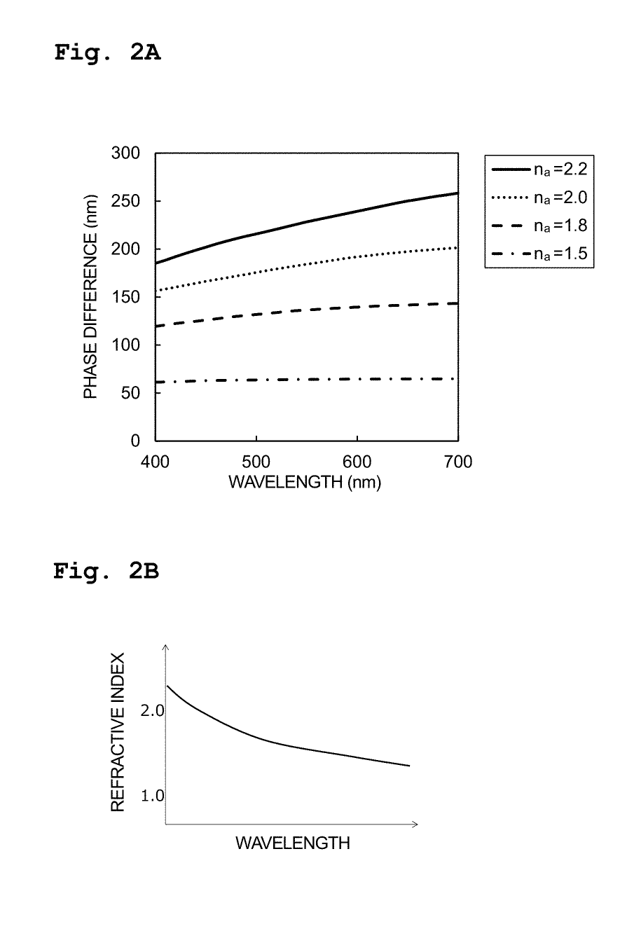

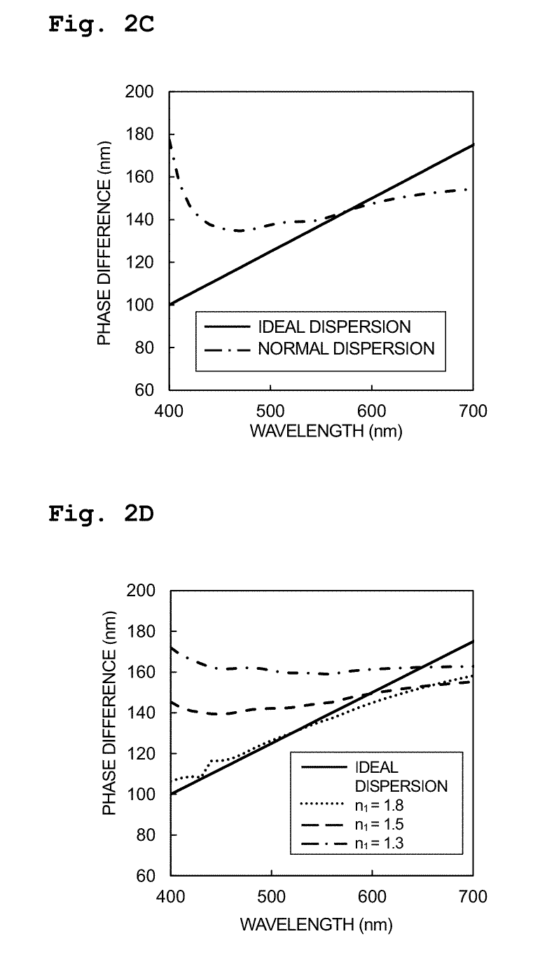

The inventors of the present application determined, by a simulation, a phase difference generated by a concave-convex structure in which linear convex portions (refractive index nₐ) are arranged at 300 nm pitches, the linear convex portions each having a cross-section perpendicular to its extending direction in which the base is 300 nm and the height is 1000 nm. Namely, the inventors determined, by the simulation, a phase difference generated by an interface between the convex portion having the refractive index nₐ and an air layer having a refractive index of one. Assuming that the refractive index nₐ is constant without depending on a wavelength, as depicted in FIG. 2A, the phase difference increases as the refractive index nₐ is greater (i.e., as the difference in refractive indexes (nₐ−1) between the convex portion and air is greater). This means that an interface between materials having a great difference in refractive indexes therebetween generates a phase difference greater than that of an interface between materials having a small difference in refractive indexes therebetween. Thus, the conventional optical phase difference component as described above can generate a sufficient degree of phase difference by forming the coating layer by use of a high refractive index material and making the difference in refractive indexes between air and the coating layer and the difference in refractive indexes between the coating layer and the convex portion large.

In the simulation result depicted in FIG. 2A, the change rate of the phase difference to the wavelength (slope of each phase difference curve) is greater as the refractive index nₐ is greater. It means that the reverse dispersibility of phase difference increases as the refractive index nₐ is greater (i.e., the difference in refractive indexes (nₐ−1) between the convex portion and air is greater), assuming that the refractive index nₐ is constant without depending on the wavelength. In other words, the reverse dispersibility of phase difference generated by the interface increases as the difference in refractive indexes between materials on both sides of the interface is greater, assuming that the refractive index nₐ is constant without depending on the wavelength. Thus, in the optical phase difference component 100 depicted in FIG. 1A, when the wavelength dependence of the refractive index n₁ of the convex portions 60 is not considered, it is estimated that the reverse dispersibility of phase difference generated by the interface between the coating layer 30 and the convex portion 60 decreases as the difference in refractive indexes (n₂−n₁) between the coating layer 30 and the convex portion 60 is smaller.

However, as indicated in FIG. 2B, an actual high refractive index material typically has a refractive index depending on the wavelength, and the refractive index is higher as the wavelength is shorter. This means that the difference in refractive indexes between air and the coating layer and the difference in refractive indexes between the coating layer and the convex portion increase as the wavelength is shorter. Thus, as depicted by a dot-dash chain line in FIG. 2C, a conventional optical phase difference component using such a high refractive index material has a phase difference property in which the phase difference is greater as the wavelength is shorter (in the present application, such a phase difference property is referred to as normal dispersion). In FIG. 2C, the phase difference property of ideal dispersion is depicted by a solid line. Accordingly there is a problem that, even though the high refractive index material is used to obtain the reverse dispersibility, it is impossible to obtain sufficient reverse dispersibility because the wavelength dispersion of the refractive index of the high refractive index material itself is high.

In this embodiment, the phase difference property of the optical phase difference component 100 is generally produced by combining the phase difference property obtained from the interface between the gap (air) 90 and the coating layer 30 and the phase difference property obtained from the interface between the coating layer 30 and the convex portion 60. Since the refractive index of the convex portions 60 is greater than that of air, the difference in refractive indexes between the coating layer 30 and the convex portion 60 is smaller than the difference in refractive indexes between the gap (air) 90 and the coating layer 30. Thus, it is estimated that the phase difference generated in the interface between the coating layer 30 and the convex portion 60 has the reverse dispersibility lower than that of the phase difference generated in the interface between the gap (air) 90 and the coating layer 30. Here, it is estimated that, if a contribution of the phase difference property obtained from the interface between the coating layer 30 and the convex portion 60 that has small reverse dispersibility is decreased, a contribution of the phase difference property obtained from the interface between the gap (air) 90 and the coating layer 30 that has high reverse dispersibility is increased, improving the reverse dispersibility of the phase difference of the optical phase difference component that is obtained by combining both the phase difference properties.

The inventors of the present application actually simulated the wavelength dependence of the phase difference generated by the optical phase difference component 100 of this embodiment, assuming that the refractive index n₁ of the convex portions 60 is each value (1.3, 1.5, 1.8) not depending on the wavelength and that the refractive index n₂ of the coating layer 30 is a value having the wavelength dependence depicted in FIG. 2B. As a result, it is revealed that, as estimated above, the phase difference property of the optical phase difference component 100 becomes the reverse dispersion close to the ideal dispersion (see FIG. 2D; in FIG. 2D, the phase difference property of ideal dispersion is depicted by a solid line), as the refractive index n₁ of the convex portions 60 is greater (i.e., as the contribution of the phase difference property obtained from the interface between the coating layer 30 and the convex portion 60 to the phase difference properties of the optical phase difference component 100 is smaller by making the difference in refractive indexes (n₂−n₁) between the coating layer 30 and the convex portion 60 smaller to make the phase difference generated in the interface between the coating layer 30 and the convex portion 60 smaller). Namely, it is revealed that a deficiency of the reverse dispersibility due to the wavelength dependence of the refractive index of the high refractive index material forming the coating layer 30 can be compensated by making the refractive index n₁ of the convex portion 60 high.

When n₂−n₁>0.8 is satisfied and light enters the substrate 42 from an oblique direction, a component of a short wavelength, such as blue color, is easily scattered by an interface between the concave-convex structure layer 50 and the coating layer 30, causing a problem in which the optical phase difference component looks yellow when seen from the oblique direction. The optical phase difference component 100 of this embodiment, however, satisfies n₂−n₁≤0.8, thus preventing light from being scattered by the interface between the concave-convex structure layer 50 and the coating layer 30 and capable of satisfactorily transmitting the light having a short wavelength that is easily scattered. Accordingly, the optical phase difference component 100 of this embodiment reduces the yellow when seen from the oblique direction and achieves a wide viewing angle.

In place of the transparent base 40 in which the concave-convex structure layer 50 is formed on the substrate 42, a transparent base 40a, in which structures forming convex portions 60a are formed on a substrate 42a, may be used, as in an optical phase difference component 100a depicted in FIG. 1B. In the transparent base 40a, concave portions 70a (areas where a surface of the substrate 42a is exposed) are defined between convex portions 60a to form a concave-convex pattern 80a configured by the convex portions 60a and concave portions 70a. A substrate similar to the substrate 42 of the optical phase difference component 100 depicted in FIG. 1A may be used as the substrate 42a. Examples of materials of the convex portions 60a may be the same as those of the concave-convex structure layer 50 of the optical phase difference component 100 depicted in FIG. 1A.

Further, as in an optical phase difference component 100b depicted in FIG. 1C, a transparent base 40b may be configured by a substrate of which surface forms a concave-convex pattern 80b including convex portions 60b and concave portions 70b. In that case, the transparent base 40b may be formed to include the concave-convex pattern 80b as depicted in FIG. 1C.

In each of the optical phase difference components 100, 100a, and 100b, a protective component, such as a protective sheet, may adhere to the closing layer and/or the surface, of the transparent base 40, 40a, or 40b, opposite to the surface with the concave-convex pattern 80, 80a, or 80b. This prevents each of the optical phase difference components 100, 100a, and 100b from being damaged or scarred which would be otherwise caused when each of the optical phase difference components 100, 100a, and 100b is transported, conveyed, or the like.

[Manufacturing Apparatus of Optical Phase Difference Component]

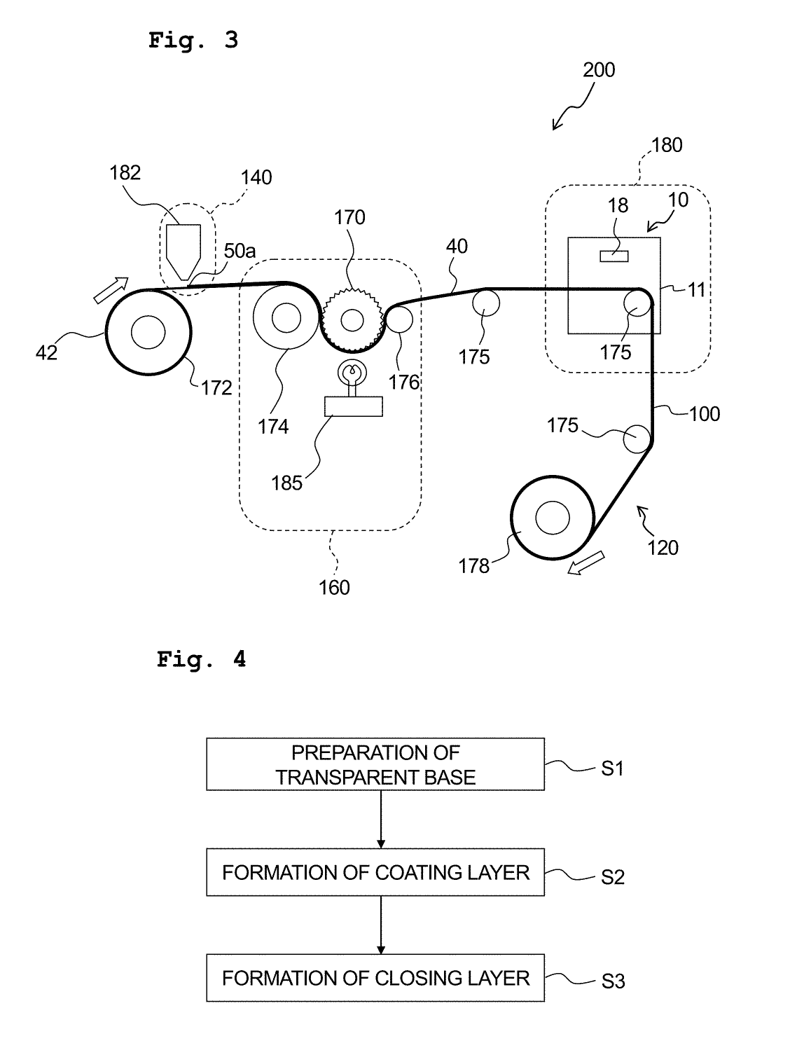

FIG. 3 depicts a roll process apparatus 200 as an exemplary apparatus for manufacturing the optical phase difference component. The following describes a configuration of the roll process apparatus 200.

The roll process apparatus 200 mainly includes a transport system 120 transporting the film-shaped substrate 42, a coating unit 140 coating the substrate 42 being transported with a UV curable resin, a transfer unit 160 transferring a concave-convex pattern to the UV curable resin, and a film formation unit (deposition unit) 180 forming the coating layer and the closing layer on the concave-convex pattern.

The transport system 120 includes a feeding roll 172 that feeds the film-shaped substrate 42, a nip roll 174 and a peeling roll (releasing roll) 176 that are respectively arranged upstream and downstream of a transfer roll 170 provided in the transfer unit 160 and urge the substrate 42 toward the transfer roll 170, and a winding roll 178 that winds or rolls up the obtained optical phase difference component 100 thereon. The transport system 120 includes guide rolls 175 transporting the substrate 42 to the respective components or parts described above. The coating unit 140 includes a die coater 182 that coats the substrate 42 with a UV curable resin 50a. The transfer unit 160 is disposed downstream of the coating unit 140 in a substrate transporting direction. The transfer unit 160 includes the transfer roll 170 including a concave-convex pattern that will be described later and a radiation light source 185 disposed to face the transfer roll 170 with the substrate 42 intervening therebetween. The film formation unit 180 includes a film formation device (deposition system), such as a sputtering device 10. The sputtering device 10 includes a vacuum chamber 11. Although the vacuum chamber 11 typically has a rectangular parallelepiped shape or cylindrical shape, the vacuum chamber 11 may be any shape provided that the inside of the vacuum chamber 11 is kept in a decompressed state. In the vacuum chamber 11, a sputtering target 18 is disposed to face a surface, of the transparent base 40 being transported, formed with the concave-convex pattern. When the coating layer and closing layer that are made from the inorganic material(s) such as metal, metal oxide, metal nitride, metal sulfide, metal oxynitride, and metal halide, are formed on the concave-convex pattern, a target made from the inorganic material(s) such as metal, metal oxide, metal nitride, metal sulfide, metal oxynitride, and metal halide may be used as the sputtering target 18.

The transfer roll 170 is a mold in a roll-shape (column shape, cylindrical shape) having an outer circumference surface with the concave-convex pattern. The transfer roll 170 may be manufactured by a method described, for example, in WO2016/056277.

[Method for Manufacturing Optical Phase Difference Component]

The following explanation will be made on a method for manufacturing the optical phase difference component 100 depicted in FIG. 1A by use of the roll process apparatus 200. As indicated in FIG. 4, the method for manufacturing the optical phase difference component mainly includes a step S1 of preparing the transparent base with the concave-convex pattern, a step S2 of forming the coating layer that coats concave portions and convex portions of the concave-convex pattern, and a step S3 of forming the closing layer on the concave-convex pattern of the transparent base.

<Step of Preparing Transparent Base>

In the method for manufacturing the optical phase difference component of this embodiment, the transparent base with the concave-convex pattern is prepared as follows (step S1 of FIG. 4). In the roll process apparatus 200 depicted in FIG. 3, rotation of the film feeding roll 172 feeds the film-shaped substrate 42 wound around the film feeding roll 172 to a downstream side. The film-shaped substrate 42 is transported to the coating unit 140 and coated with the UV curable resin 50a having a predefined thickness by use of the die coater 182.

As a method for coating the substrate 42 with the UV curable resin 50a, instead of the die coating method, it is possible to adopt, for example, various coating methods such as the bar coating method, spin coating method, spray coating method, dip coating method, dropping method, gravure printing method, screen printing method, relief printing method, die coating method, curtain coating method, ink-jet method, and sputtering method. Among them, the bar coating method, die coating method, gravure printing method and spin coating methods may be adopted because a substrate having a relatively large area can be coated uniformly with the UV curable resin 50a.

In order to improve the adhesion property between the substrate 42 and the UV curable resin 50a, a surface modified layer may be provided on the substrate 42 before the substrate 42 is coated with the UV curable resin 50a. Examples of materials of the surface modified layer include materials described, as materials of the surface modified layer, in WO2016/056277. Alternatively, a surface modified layer may be provided in such a manner that the surface of the substrate 42 is subjected to treatment with an energy ray, such as plasma treatment, corona treatment, excimer irradiation treatment, or UV/O₃ treatment.

The film-shaped substrate 42 coated with the UV curable resin 50a by the coating unit 140 is transported to the transfer unit 160. In the transfer unit 160, the film-shaped substrate 42 is pressed (urged) against the transfer roll 170 by use of the nip roll 174, so that the concave-convex pattern of the transfer roll 170 is transferred to the UV curable resin 50a, and at the same time or immediately after the above, the radiation light source 185, which is disposed to face the transfer roll 170 with the film-shaped substrate 42 intervening therebetween, emits UV light to the UV curable resin 50a, thus curing the UV curable resin 50a. The cured UV curable resin and the film-shaped substrate 42 are peeled off from the transfer roll 170 by use of the peeling roll 176. Accordingly, the transparent base 40 with the concave-convex structure layer 50 (see FIG. 1A) to which the concave-convex pattern of the transfer roll 170 has been transferred is obtained.

The transparent base with the concave-convex pattern may be manufactured by an apparatus other than the roll process apparatus depicted in FIG. 3. The transparent base with the concave-convex pattern is not required to be self-manufactured, and it may be obtained through a manufacturer such as a market and film manufacturer.

<Step of Forming Coating Layer>

Subsequently, the transparent base 40 with the concave-convex pattern is transported to the film formation unit 180, and the coating layer 30 (see FIG. 1A) is formed on surfaces of concave portions and convex portions of the concave-convex pattern of the transparent base 40 (step S2 of FIG. 4). In the roll process apparatus 200 depicted in FIG. 3, the transparent base 40 peeled from the transfer roll 170 is transported directly into the sputtering device 10 via the guide roll 175. The transparent base 40 peeled from the transfer roll 170, however, may be rolled into a roll, and the obtained rolled transparent base 40 may be transported into the sputtering device 10.

The following explanation will be made on a method for forming the coating layer 30 (see FIG. 1A) that is made from, for example, metal oxide with the sputtering device 10 depicted in FIG. 3. At first, pressure in the vacuum chamber 11 is reduced to high vacuum. Then, the transparent base 40 is transported to a position facing the sputtering target 18 while a noble gas, such as Ar, and an oxygen gas are being introduced into the vacuum chamber 11, and metal atoms (and oxygen atoms) are sputtered from the sputtering target 18 by DC plasma or high-frequency plasma. The metal atoms sputtered from the sputtering target 18 react with oxygen on the surface of the transparent base 40 to cause deposition of metal oxide, while the transparent base 40 is being transported in the vacuum chamber 11. Accordingly, the coating layer 30 (see FIG. 1A) is formed on the transparent base 40, along the concave-convex pattern 80, to coat the convex portions 60 and concave portions 70.

<Step of Forming Closing Layer>

Next, the closing layer 20 (see FIG. 1A) is formed on the transparent base 40 (step S3 of FIG. 4). The closing layer 20 can be formed continuously from the formation of the coating layer 30 with the sputtering device 10 used in the step S2 of forming the coating layer. When the closing layer 20 is made from the same metal oxide as the coating layer 30, metal oxide can be further deposited on the transparent base 40 by performing sputtering from the target 18 continuously after formation of the coating layer 30. In that situation, the sputtered metal atoms are not likely to reach gaps between adjacent convex portions 60 (see FIG. 1A) of the concave-convex pattern 80 of the transparent base 40, in particular, the sputtered metal atoms are not likely to reach lower side surfaces (side surfaces on the substrate 42 side) of the convex portions 60 of the concave-convex pattern 80 of the transparent base 40. Namely, most of the metal atoms adhere to upper surfaces 60t and upper side surfaces of the convex portions 60. Thus, the deposition amount of metal oxide on the upper parts (upper surfaces 60t and upper side surfaces) of the convex portions 60 is larger than that on the concave portions 70 and the lower side surfaces of the convex portions 60. Accordingly, performing sputtering continuously allows the metal oxide deposited on the upper parts of adjacent convex portions 60 to connect with each other to form the closing layer 20 before the gaps between adjacent convex portions 60 are filled with the deposited metal oxide, thus forming the gaps 90 between adjacent convex portions 60. The gaps 90 are closed by the coating layer 30 and the closing layer 20. Especially, when the top (upper surface) 60t of each convex portion 60 is a surface parallel to the substrate 42, i.e., a surface parallel to the sputtering target 18 (for example, when the cross-sectional structure in a plane orthogonal to the extending direction of each convex portion 60 has a trapezoidal shape), the metal oxide is much more likely to be deposited on the upper surfaces 60t of the convex portions 60 than on other portions. This can reduce the deposition time that is required for connecting the metal oxide deposited on the upper parts of adjacent convex portions 60 to form the closing layer 20, and also reduce material (target) consumption.

When the closing layer 20 and the coating layer 30 are made from the same material, formation of the closing layer 20 proceeds simultaneously with formation of the coating layer 30 until the metal oxide deposited on the upper parts of adjacent convex portions 60 connect to each other in the step of forming the closing layer. Namely, in that case, the step S2 of forming the coating layer is not independent of the step S3 of forming the closing layer. The step S2 overlaps with the step S3.

The coating layer 30 and closing layer 20 may be formed by a publicly known dry process, such as a physical vapor deposition method (PVD) including evaporation and the like or a chemical vapor deposition method (CVD), instead of the sputtering described above. For example, when metal oxide films are formed as the coating layer 30 and the closing layer 20 on the transparent base 40 by an electron beam heating evaporation method, it is possible to use, for example, an electron beam heating evaporation apparatus configured as follows. Namely, in a vacuum chamber, there are provided a crucible that contains metal or metal oxide to form the coating layer 30 and the closing layer 20 and an electron gun that irradiates the interior of the crucible with an electron beam to evaporate metal or metal oxide. The crucible is disposed to face a transport path of the transparent base 40. The coating layer 30 and the closing layer 20 can be formed on the transparent base 40 by heating and evaporating the metal or metal oxide in the crucible by the electron beam while transporting the transparent base 40 and depositing the metal oxide on the transparent base 40 being transported. Further, it is allowable to or not to introduce the oxygen gas into the vacuum chamber depending on the degree of oxidation of the material contained in the crucible and a targeted degree of oxidation of the coating layer and the closing layer.

When the metal oxide films are formed as the coating layer 30 and the closing layer 20 on the transparent base 40 by atmospheric-pressure plasma CVD, it is possible to use methods described, for example, in Japanese Patent Application Laid-open Nos. 2004-052028 and 2004-198902. An organometallic compound may be used as a raw material compound, and the raw material compound may be in either a gaseous, liquid, or solid state at normal temperature under normal pressure. When the raw material compound is used in its gaseous state, the raw material compound can be introduced as it is into a discharge space; on the other hand, when the raw material compound is in a liquid or solid state, the material is used after being gasified once by means of heating, bubbling, decompression, ultrasonic radiation, etc. In view of such a situation, for example, a metal alkoxide of which boiling point is not more than 200° C. is preferably used as the organometallic compound.

Examples of such a metal alkoxide include those described in WO2016/056277.

Further, a cracking gas is used together with the gaseous raw material containing these organometallic compounds to compose a reactive gas, for the purpose of cracking the organometallic compounds to thereby obtain an inorganic compound. The cracking gas is exemplified, for example, by those described in WO2016/056277. For example, metal oxide can be formed by using the oxygen gas, metal nitride can be formed by using an ammonia gas, and metal oxynitride can be formed by using the ammonia gas and a nitrous oxide gas.

In the plasma CVD method, a discharge gas easily turned to a plasma state is mainly mixed with the reactive gas. As the discharge gas, it is possible to use a nitrogen gas; a rare gas such as a gas of an element of the eighteenth group of the periodic table, specifically, helium, neon, argon, etc.; and the like. In particular, the nitrogen gas may be used in view of the production cost.

The film formation is performed by mixing the discharge gas with the reactive gas to thereby obtain a mixed gas, and by supplying the mixed gas to a discharge plasma generating apparatus (plasma generator). The ratio of the discharge gas relative to the reactive gas is different depending on the property of a film as an object to be formed, and the percentage of the discharge gas in the entire mixed gas is not less than 50%.

For example, silicon alkoxide (such as tetraethoxysilane (TEOS)), which is one of the metal alkoxides having a boiling point of not more than 200° C., is used as the raw material compound, oxygen is used as the cracking gas, and the rare gas or the inert gas such as nitrogen is used as the discharge gas, and the plasma discharge is performed. Thus, it is possible to form a film of silicon oxide.

In the CVD method as described above, it is possible to deposit any one of metal carbide, metal nitride, metal oxide, metal sulfide, metal halide, or mixtures thereof (e.g., metal oxynitride, metal oxide halide, and metal nitride carbide) by selecting conditions such as the metal compound as the raw material, cracking gas, decomposition temperature, and power to be inputted or supplied. Thus, the film is preferably obtained by the CVD method.

As described above, the optical phase difference component 100 as depicted in FIG. 1A is obtained. The optical phase difference component 100 obtained may be wound around the winding roll 178. The optical phase difference component 100 may pass through the guide roll 175 or the like on the way, as appropriate. The protective component may adhere to the surface, of the transparent base 40, opposite to the surface with the concave-convex pattern 80 and/or the closing layer 20. This prevents the optical phase difference component 100 from being damaged or scarred when the obtained optical phase difference component 100 is transported or conveyed.

Although the transfer roll is used as the mold for transferring the concave-convex pattern to the UV curable resin in the above embodiment, a long film-shaped mold, plate-shaped mold, or the like may be pressed against the UV curable resin applied on the substrate to form the concave-convex pattern.

Although the concave-convex structure layer 50 is made from the UV curable resin in the above embodiment, the concave-convex structure layer 50 may be made from, for example, a thermoplastic resin, thermosetting resin, or inorganic material. When the concave-convex structure layer 50 is made from the inorganic material, the transparent base 40 can be prepared, for example, by a method of coating a mold with a precursor of the inorganic material and curing the coating film; a method of coating a mold with a dispersion liquid of fine particles and drying the dispersion medium; a method of coating a mold with a resin material and curing the coating film; or a liquid phase deposition (LPD) method.

As the precursor of the inorganic material, materials described in WO2016/056277 may be used. For example, it is possible to use alkoxide (metal alkoxide), such as Si, Ti, Sn, Al, Zn, Zr, or In (sol-gel method).

Examples of a solvent of the precursor solution used in the sol-gel method include those described in WO2016/056277.

As an additive to the precursor solution used in the sol-gel method, it is possible to use those described in WO2016/056277.

As the precursor of the inorganic material, polysilazane described in WO2016/056277 may be used.

The substrate is coated with the solution of the precursor of the inorganic material, such as the above metal alkoxide or polysilazane, and then the coating film of the precursor is heated or irradiated with energy rays while a mold having a concave-convex pattern is pressed against the coating film of the precursor, thus causing gelation of the coating film. Accordingly, the concave-convex structure layer that is made from the inorganic material and to which the concave-convex pattern of the mold has been transferred is obtained.

The transparent base 40a, as depicted in FIG. 1B, in which structures forming convex portions 60a are formed on the substrate 42a and areas (concave portions 70a) where the surface of the substrate 42a is exposed are defined between convex portions 60a can be manufactured, for example, as follows. Instead of coating the substrate 42 with the UV curable resin 50a in the manufacturing method described above, only the concave portions or only the convex portions of the mold for concave-convex pattern transfer are coated with UV curable resin. The UV curable resin coating the mold is brought in tight contact with the substrate 42a, thus transferring the UV curable resin to the substrate 42a. Accordingly, the convex portions 60a having a shape corresponding to the shape of the concave portions or a shape corresponding to the shape of the convex portions of the mold are formed on the substrate 42a. The concave portions 70a (areas where the surface of the substrate 42a is exposed) are defined between the convex portions 60 formed as described above.

The transparent base 40b, as depicted in FIG. 1C, formed from a substrate of which surface forms the concave-convex pattern having the convex portions 60b and concave portions 70b, can be manufactured, for example, as follows. A resist layer having a concave-convex pattern is formed on a substrate by publicly known technology, such as nanoimprint or photolithography. Concave portions of the resist layer are etched to expose a surface of the substrate, and then the substrate is etched using a remaining resist layer as a mask. After etching, a residual mask (resist) is removed by a medicinal solution. Accordingly, the concave-convex pattern 80b can be formed on the substrate surface itself.

The coating layer 30 and the closing layer 20 are formed on each of the transparent bases 40a and 40b manufactured as described above by the method similar to the above embodiment, thus forming each of the optical phase difference component 100a depicted in FIG. 1B and the optical phase difference component 100b depicted in FIG. 1C.

<Composite Optical Component>

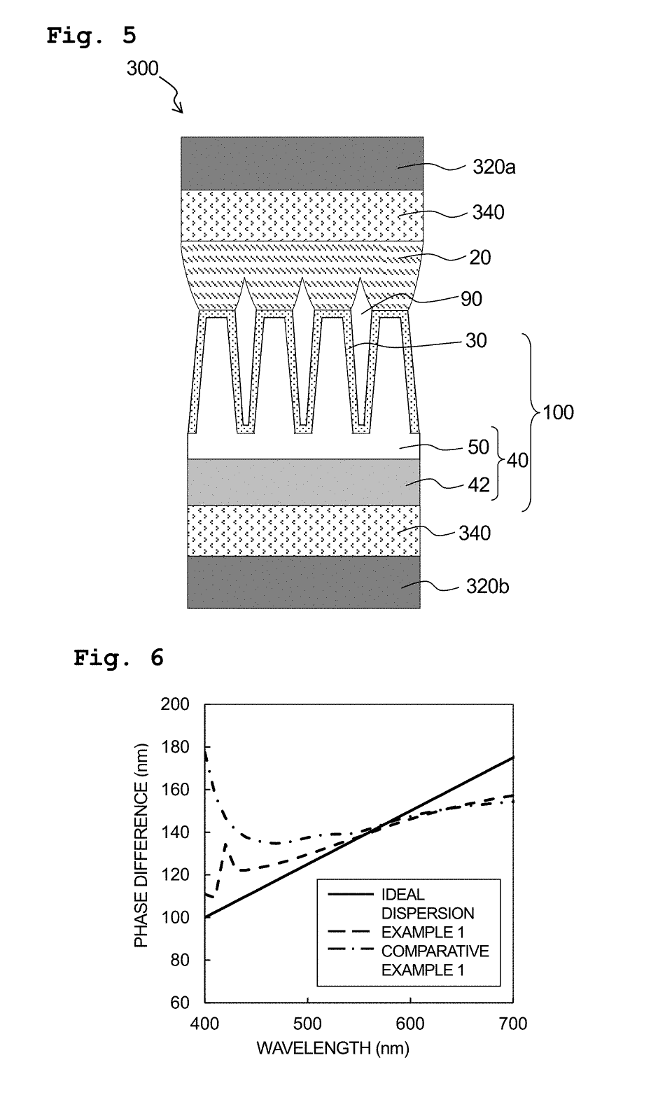

The following explanation will be made on a composite optical component formed by using any one of the optical phase difference components 100, 100a, and 100b. As depicted in FIG. 5, a composite optical component 300 is configured by the optical phase difference component 100 of the above embodiment, and optical components 320a and 320b joined to the optical phase difference component 100. In the composite optical component 300, the optical component 320a is joined (adheres) to the closing layer 20 of the optical phase difference component 100, and the optical component 320b is joined to the surface, of the transparent base 40, opposite to the surface with the concave-convex pattern. The composite optical component according to the present teaching is not required to include both the optical components 320a and 320b, namely, any one of the optical components 320a and 320b may be provided in the composite optical component according to the present teaching. For example, the composite optical component, in which a polarization plate as the optical component 320a or 320b adheres to the optical phase difference component 100, may be used as an antireflection film. By allowing an optical phase difference component side of the antireflection film to adhere to a display element such as an organic EL element (organic Electro-Luminescence element or organic light emitting diode) and a liquid crystal element, it is possible to obtain a display device (e.g., an organic EL display and a liquid crystal display) that is not likely to cause reflection of wiring electrodes of the display element.

Adhesive is used to join the optical phase difference component to the optical components such as the polarization plate and display element. As the adhesive, any publicly known adhesive, such as acrylic-based or silicone-based adhesive, may be used. In the optical phase difference component of this embodiment, the gaps between convex portions are closed by or covered with the closing layer. This prevents the adhesive from entering the gaps between convex portions. Therefore, the phase difference generated by the optical phase difference component remains unchanged after the optical phase difference component is joined to the optical components, and thus the optical phase difference component can generate a sufficient phase difference.

In the optical phase difference component of the above embodiments, each of the convex portions of the concave-convex pattern may have a substantially trapezoidal cross-sectional shape.

In the optical phase difference component of the above embodiments, the gap may have a height equal to or higher than that of each of the convex portions of the concave-convex pattern.

In the optical phase difference component of the above embodiments, the coating layer and the closing layer may be made from metal, metal oxide, metal nitride, metal sulfide, metal oxynitride, or metal halide.

In the optical phase difference component of the above embodiments, the concave-convex pattern may be made from a photo-curable resin or a thermo-setting resin.

In the optical phase difference component of the above embodiments, the concave-convex pattern may be made from a sol-gel material.

In the optical phase difference component of the above embodiments, the gap may contain air.

In the forming of the coating layer and the forming of the closing layer in the method for manufacturing the optical phase difference component of the above embodiments, the coating layer and the closing layer may be formed by sputtering, CVD, or evaporation deposition.

As described above, in the optical phase difference component of the present teaching, the gap between adjacent convex portions of the concave-convex pattern (concave-convex structure) of the base is closed with the closing layer and the concave-convex pattern. This prevents adhesive from entering the gap between the convex portions of the concave-convex pattern when the optical phase difference component is incorporated into a device, preventing the difference in refractive indexes between a material of convex portions and a material of the gap between convex portions from decreasing. Thus, refractive index anisotropy of the optical phase difference component is prevented from decreasing. Accordingly, the optical phase difference component of the present teaching can have a good phase difference property even after being incorporated into a device. Further, since the closing layer is formed on the convex portions of the concave-convex pattern and above the gap so as to connect or bridge adjacent convex portions, the convex portions of the concave-convex pattern are not likely to be deformed when a load is applied thereto. This prevents a situation in which the optical phase difference component can not generate a desired phase difference. The optical phase difference component of the present teaching has a phase difference property of reverse dispersion by making the difference in refractive indexes between the convex portion and the coating layer coating the convex portion equal to or less than 0.8. Thus, an antireflection film formed by using the optical phase difference component of the present teaching has low reflectance in a visible region and causes less coloring. Further, the optical phase difference component of the present teaching has a wide viewing angle. Therefore, the optical phase difference component of the present teaching is suitably used for the antireflection film of a display device, and the like.

### EXAMPLES

In the following description, the optical phase difference component according to the present teaching will be specifically explained with examples and comparative examples. The present teaching, however, is not limited to the examples and comparative examples.

### Example 1

A structure of an optical phase difference component was calculated by simulation, the optical phase difference component obtained by depositing a high refractive index material on a transparent base so that its deposition thickness was 600 nm. The high refractive index material had the refractive index n₂ of 2.37 at a wavelength of 550 nm and an Abbe's number of 31. In the transparent base, a pitch of the concave-convex pattern was 240 nm, a width of an upper surface of each convex portion was 0 nm, a distance between bottoms of adjacent convex portions was 50 nm, a height of each convex portion was 350 nm, the refractive index n₁ of each convex portion at a wavelength of 550 nm was 1.72, and the Abbe's number was 13. In this Example, the difference (n₂−n₁) between the refractive index n₁ of each convex portion and the refractive index n₂ of the coating layer at a wavelength of 550 nm was 0.65. The deposition thickness means a thickness, of the film formed on the top (upper surface) of the convex portion, in a direction perpendicular to a surface (concave-convex pattern surface) of the transparent base. The deposition thickness is a maximum value of the thickness, of the film formed on the surface of the transparent base, in the direction perpendicular to the surface of the transparent base. The deposition thickness is substantially the same as a thickness of a film formed when each material is deposited on a flat substrate under the same conditions. The optical phase difference component had a coating layer made from a high refractive index material and coating the concave-convex pattern and a closing layer made from a high refractive index material and connecting upper surfaces (tops) of adjacent convex portions.

The phase difference that was generated in incident light at wavelengths of 400 to 700 nm by the optical phase difference component having the structure determined from the above calculation, was calculated. The calculation result of phase difference is depicted by a broken line in FIG. 6. In FIG. 6, a horizontal axis indicates a wavelength of incident light and a vertical axis indicates a phase difference. The phase difference in a case of the ideal dispersion is depicted by a solid line in FIG. 6.

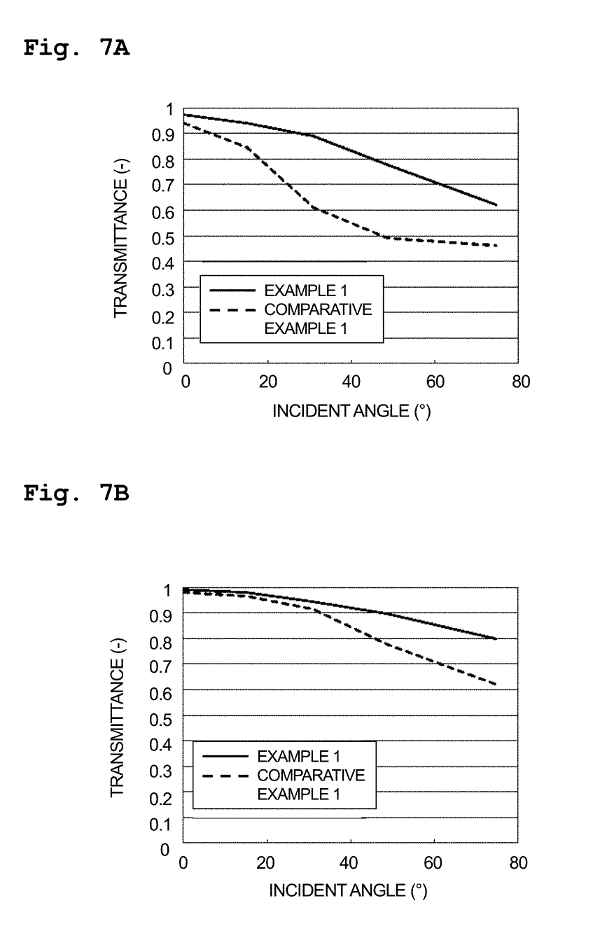

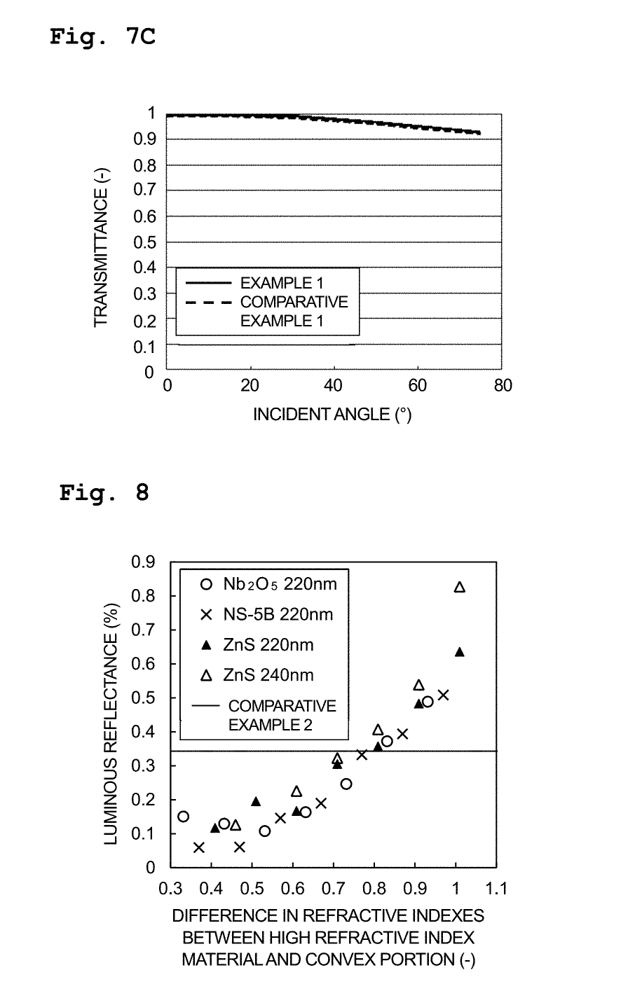

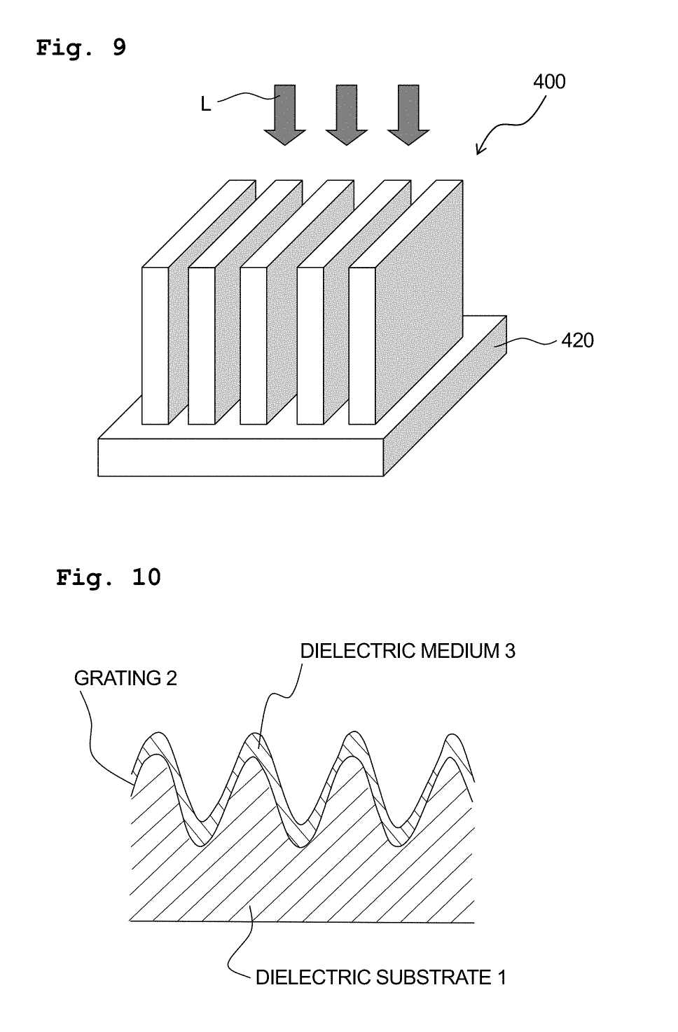

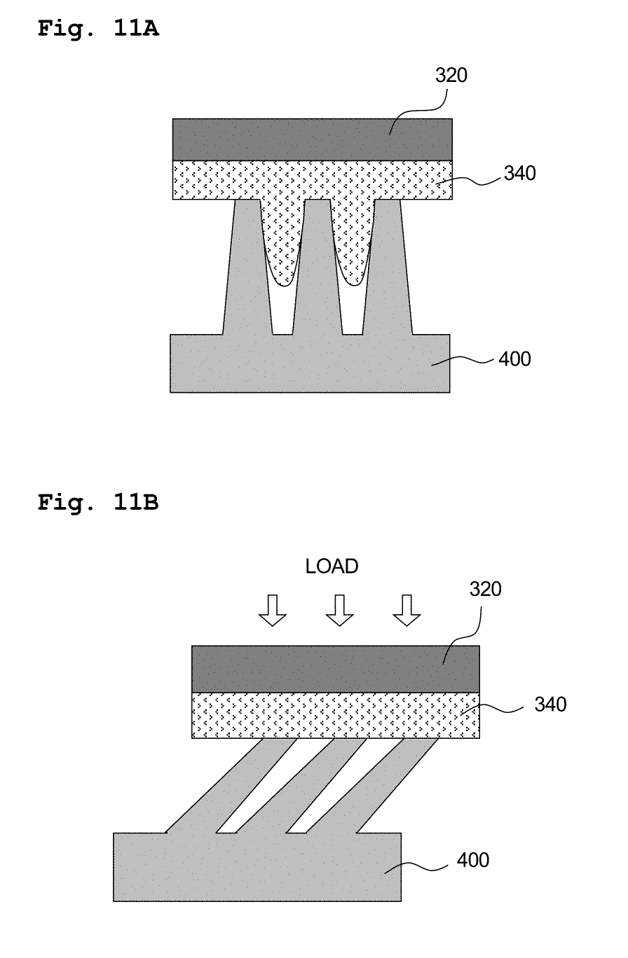

The transmittance of when light entered, at incident angles of 0° to 80°, the optical phase difference component having the structure determined from the calculation, was calculated by a Rigorous Coupled Wave Analysis (RCMA). Solid lines in FIGS. 7A to 7C indicate calculation results of the transmittance. FIG. 7A indicates an average value of the transmittance of light at wavelengths of 430 to 500 nm as the transmittance of blue light; FIG. 7B indicates an average value of the transmittance of light at wavelengths of 500 to 590 nm as the transmittance of green light; and FIG. 7C indicates an average value of the transmittance of light at wavelengths of 590 to 680 nm as the transmittance of red light.

### Example 2

An optical phase difference component having the same structure as Example 1 was manufactured as described below. At first, a glass substrate (OA-10G produced by Nippon Electric Glass Co., Ltd.) was prepared. A surface of the glass substrate was coated with an ultraviolet curable polyphenylene sulfide resin to form a coating film. Next, the coating film was cured with ultraviolet irradiation while a mold for imprinting was pressed thereagainst, and then the mold was released from the coating film. Accordingly, a concave-convex structure layer made from polyphenylene sulfide was formed on the surface of the glass substrate. A flat film made from polyphenylene sulfide had a refractive index of 1.72 at a wavelength 550 nm which was measured by spectroscopic ellipsometry.

ZnS (refractive index 2.37) as a high refractive index material was deposited by performing sputtering on the concave-convex structure layer so that the deposition thickness was 600 nm. As a result, an optical phase difference component having a coating layer made from a high refractive index material and coating the concave-convex pattern and a closing layer made from a high refractive index material and connecting upper surfaces (tops) of adjacent convex portions, was obtained.

The closing layer of the obtained optical phase difference component adhered to a polarization plate with paste (SRW062 produced by Sumitomo Chemical Co., Ltd.), manufacturing an antireflection component. The antireflection component was placed on an organic EL light source (organic Electro-Luminescence light source or organic light emitting diode light source) of white color and visually observed from a front side and an oblique direction. The antireflection component looked white when seen from the front side, but looked yellow tinge from the oblique direction.

### Comparative Example 1

The phase difference generated in the incident light by the optical phase difference component and the transmittance of when light entered the optical phase difference component at incident angles of 0° to 80° were calculated similarly to Example 1, except that the refractive index n₁ of the convex portion at a wavelength of 550 nm was 1.52 and the Abbe's number was 68. In this Comparative Example, the difference (n₂−n₁) between the refractive index n₁ of the convex portion and the refractive index n₂ of the coating layer at a wavelength of 550 nm was 0.85. The calculation result of the phase difference was depicted by a dot-dash chain line in FIG. 6. The calculation results of the transmittance were depicted by broken lines in FIGS. 7A to 7C.

### Comparative Example 2

An optical phase difference component having the same structure as Comparative Example 1 was manufactured similarly to Example 2, except that a concave-convex structure layer made from a resin NIF13g99 (refractive index 1.52) produced by Asahi Glass Co., Ltd was formed.

An antireflection component was manufactured similarly to Example 2 by using the obtained optical phase difference component. The antireflection component was placed on the organic EL light source of white color, and was visually observed from a front side and an oblique direction. The antireflection component looked white from the front side, but looked yellow from the oblique direction. The antireflection component looked yellower than the antireflection component of Example 2 when seen from the oblique direction.

The calculation results of phase difference in Example 1 and Comparative Example 1 indicate the following facts. As indicated in FIG. 6, regarding Comparative Example 1 in which the difference (n₂−n₁) at a wavelength of 550 nm was 0.85, the phase difference generated in a short wavelength area (400 to 550 nm) was large and deviated from the ideal dispersion. Regarding Example 1 in which the difference (n₂−n₁) at a wavelength of 550 nm was 0.65, the phase difference generated in the short wavelength area was relatively small and close to the phase difference of the ideal dispersion. The optical phase difference component of Example 1 as a whole had a phase difference property of reverse dispersion that was close to the ideal dispersion.

The calculation results of transmittance in Example 1 and Comparative Example 1 indicate the following facts. As indicated in FIGS. 7A to 7C, the transmittance was lower as the incident angle was larger in both of Example 1 and Comparative Example 1. This tendency was more prominent as the wavelength of the incident light was shorter. However, as indicated in FIG. 7A, in a blue area (wavelengths of 430 to 500 nm) having a short wavelength, the decrease in the transmittance due to the increase in the incident angle in Example 1 was smaller than that in Comparative Example 1. Also in a green area (wavelengths 500 to 590 nm), as depicted in FIG. 7B, the decrease in the transmittance due to the increase in the incident angle in Example 1 was smaller than that in Comparative Example 1. Here, the difference in transmittance between Example 1 and Comparative Example 1 in the green area was smaller than that in the blue area. In a red area (wavelengths of 590 to 680 nm) having a long wavelength, as depicted in FIG. 7C, Example 1 and Comparative Example 1 had substantially the same transmittance at any incident angle within a range of 0° to 80°.

The transmittance characteristics described above allow the optical phase difference component of Example 1 to transmit light having a large incident angle, coming from an oblique direction, and having a short wavelength more than the optical phase difference component of Comparative Example 1. This prevents the optical phase difference component of Example 1 from looking yellow when seen from the oblique direction. Thus, the optical phase difference component of Example 1 has a larger viewing angle than that of Comparative Example 1. This is backed up by the fact that the yellow tinge observed in the visual observation from the oblique direction in Example 2 was weaker than the yellow observed in the visual observation from the oblique direction in Comparative Example 2.

### Example 3

A structure of an optical phase difference component was calculated by simulation, the optical phase difference component obtained by depositing each high refractive index material on a transparent base so that its deposition thickness was 600 nm. Each of the high refractive materials had the refractive index n₂ of 2.33, 2.37, or 2.41 at a wavelength of 550 nm. In the transparent base, a pitch of the concave-convex pattern was 220 nm or 240 nm, a width of an upper surface of each convex portion was 0 nm, a distance between bottoms of adjacent convex portions was 0.8 times as long as the pitch of the concave-convex pattern, a height of each convex portion was 250 to 500 nm, and the refractive index n₁ of each convex portion at a wavelength of 550 nm was 1.4 to 2.3. The refractive indexes n₂ of the high refractive index materials (2.33, 2.37, and 2.41) respectively correspond to refractive indexes of Nb₂O₅, NS-5B (produced by JX Nippon Mining & Metals Corporation), and ZnS. Abbe's numbers are 16.6, 14.5, and 10.5, respectively. The optical phase difference component had a coating layer made from high refractive index materials and coating the concave-convex pattern and a closing layer made from high refractive index materials and connecting upper surfaces (tops) of adjacent convex portions.

Luminous reflectance was calculated as an index of degree of coloring of an antireflection film manufactured by using each of the optical phase difference components, as follows. Namely, each of the optical phase difference components having the structure determined from the above calculation was placed on an ideal mirror (reflectance: 100%), and an ideal polarization plate (polarization degree: 1, total light transmittance: 50%) was placed on the optical phase difference component placed on the ideal mirror so that a polarization direction of the ideal polarization plate was at an angle of 45° to a slow axis of the optical phase difference component. The reflectance of when light entered the ideal mirror from above the ideal polarization plate, was calculated and the luminous reflectance was found by performing luminosity correction in accordance with the following equation (1). In the equation (1), λ represents a light wavelength, L(λ) represents spectral intensity distribution of a light source of D65, and Y(λ) represents relative luminosity of a human being. The coloring of the antireflection film using the optical phase difference component is smaller as the luminous reflectance is lower.

$$R = \frac{{\int }_{380}^{680} L ( λ ) Y ( λ ) \frac{1}{2} {cos}^{2} ( \frac{2 π {R}_{0}}{λ} ) d λ}{{\int }_{380}^{680} L ( λ ) Y ( λ ) d λ} \qquad ( 1 )$$

The height of the convex portion was changed at 25 nm intervals for each combination of the period of the concave-convex pattern, the value of the refractive index n₁ of the convex portion and the refractive index n₂ of the high refractive index material, to found lowest luminous reflectance and the height of the convex portion having the lowest luminous reflectance. FIG. 8 indicates calculation results of the lowest luminous reflectance. In FIG. 8, a horizontal axis indicates the difference (n₂−n₁) between the refractive index n₂ (i.e., the refractive index of the coating layer) of the high refractive index material and the refractive index n₁ of the convex portion at a wavelength of 550 nm, and a vertical axis indicates the luminous reflectance.

### Comparative Example 3

The luminous reflectance of a polycarbonate stretched film used conventionally and having a reverse dispersion property (the phase difference at a wavelength of 550 nm: 143.5 nm) was found similarly to Example 3. The luminous reflectance was 0.34% as indicated in FIG. 8.

As indicated in FIG. 8, it has been revealed that, when n₂−n₁≤0.8 was satisfied in Example 3, the luminous reflectance was lower than that of the conventional stretched film of Comparative Example 3. Namely, it has been revealed that the optical phase difference component satisfying n₂−n₁≤0.8 makes it possible to obtain an antireflection film having low reflectance in an entire visible region and causing less coloring than that of an antireflection film manufactured by using the conventional stretched film. The reason thereof is considered that, as indicated by the phase difference properties of the optical phase difference components in Example 1 and Comparative Example 1, the reverse dispersion of the optical phase difference component increases as the value of the difference (n₂−n₁) of the optical phase difference component is smaller, making it possible to generate the phase difference that is close to λ/4 relative to the wavelength λ in the entire visible region.

Although the present teaching has been explained as above with the embodiments, the optical phase difference component manufactured by the manufacturing method of the present teaching is not limited to the above-described embodiment, and may be appropriately modified or changed within the range of the technical ideas described in the following claims.

The antireflection film formed by using the optical phase difference component of the present teaching has low reflectance in a visible region and a wide viewing angle, and causes less coloring. The optical phase difference component of the present teaching can maintain a satisfactory phase difference property also in a state of being incorporated into a device. In the optical phase difference component of the present teaching, it is prevented that a desired phase difference can not be obtained by deformation of the concave-convex structure when a load is applied to the concave-convex structure. Thus, the optical phase difference component of the present teaching is suitably used for various devices, such as various functional components including, for example, antireflection films; display devices including, for example, reflective or semi-transmissive liquid crystal display devices, touch panels, and organic EL display devices; pickup devices for optical disks; and polarization conversion elements.

What is claimed is:

1. An optical phase difference component, comprising:
a transparent base with a concave-convex pattern having concave portions and convex portions;
a coating layer coating the concave portions and the convex portions of the concave-convex pattern;
a gap defined between the convex portions of the concave-convex pattern coated with the coating layer; and
a closing layer provided on the concave-convex pattern to connect tops of the convex portions of the concave-convex pattern and to close the gap,
wherein a refractive index n₁ of each of the convex portions and a refractive index n₂ of the coating layer at a wavelength of 550 nm satisfy n₂−n₁≤0.8.

2. The optical phase difference component according to claim 1, wherein each of the convex portions of the concave-convex pattern has a substantially trapezoidal cross-sectional shape.

3. The optical phase difference component according to claim 1, wherein the gap has a height equal to or higher than that of each of the convex portions of the concave-convex pattern.

4. The optical phase difference component according to claim 1, wherein the coating layer and the closing layer are made from metal, metal oxide, metal nitride, metal sulfide, metal oxynitride, or metal halide.

5. The optical phase difference component according to claim 1, wherein the concave-convex pattern is made from a photo-curable resin or a thermo-setting resin.

6. The optical phase difference component according to claim 1, wherein the concave-convex pattern is made from a sol-gel material.

7. The optical phase difference component according to claim 1, wherein the gap contains air.

8. A composite optical component, comprising:
the optical phase difference component as defined in claim 1; and
a polarization plate adhering to the closing layer or a surface, of the transparent base, opposite to a surface with the concave-convex pattern.

9. A display device, comprising:
the composite optical component as defined in claim 8; and
a display element adhering to the closing layer or a surface, of the transparent base, opposite to a surface with the concave-convex pattern.

10. A method for manufacturing an optical phase difference component, comprising:
preparing a transparent base with a concave-convex pattern having concave portions and convex portions;
forming a coating layer which coats surfaces of the concave portions and the convex portions of the concave-convex pattern; and
forming a closing layer on the concave-convex pattern to connect adjacent convex portions included in the convex portions coated with the coating layer and to close a gap defined between the adjacent convex portions,
wherein a refractive index n₁ of each of the convex portions and a refractive index n₂ of the coating layer at a wavelength of 550 nm satisfy n₂−n₁≤0.8.

11. The method for manufacturing the optical phase difference component according to claim 10, wherein, in the forming of the coating layer and the forming of the closing layer, the coating layer and the closing layer are formed by sputtering, CVD, or evaporation deposition.
